(19) United States
(12) Patent Application Publication
(10) Pub. No.: US 2015/0378192 A1
(43) Pub. Date: Dec. 31, 2015

(54) DISPLAY DEVICE AND MANUFACTURING METHOD THEREOF

(71) Applicant: Samsung Display Co., Ltd., Yongin-City (KR)

(72) Inventors: You Young JIN, Suwon-si (KR); Sung Hwan WON, Suwon-si (KR); Woo Jae LEE, Yongin-si (KR); Kyung Tae CHAE, Hwaseong-si (KR)

(21) Appl. No.: 14/573,931

(22) Filed: Dec. 17, 2014

(30) Foreign Application Priority Data
Jun. 25, 2014 (KR) 10-2014-0078244

(51) Int. Cl. G02F 1/1337; G02F 1/1333; H01L 27/12; G02F 1/1343; G02F 1/1335; G02F 1/1368; G02F 1/1341

(52) U.S. Cl. CPC G02F 1/1337; G02F 1/1368; G02F 1/133345; G02F 1/1341; G02F 1/133377; G02F 1/134309; G02F 1/133512; G02F 1/133514; H01L 27/1262; G02F 2001/134345

(57) ABSTRACT

A display device including: a substrate including a plurality of pixel areas; a thin film transistor formed on the substrate; a pixel electrode connected to the thin film transistor and formed on the first insulating layer; a liquid crystal layer filling a microcavity formed on the pixel electrode; a common electrode separated from the pixel electrode by the microcavity; a second insulating layer and a roof layer formed on the common electrode; an injection hole formed a side of the microcavity to expose a portion of the microcavity; an alignment layer formed inside the microcavity and on a surface of the injection hole; a third insulating layer formed on the roof layer; a blocking film formed at a position corresponding to the injection hole on the alignment layer; and an overcoat covering the injection hole to seal the microcavity and formed on the third insulating layer and the blocking film.

### CROSS-REFERENCE TO RELATED APPLICATION

This application claims priority to and the benefit of Korean Patent Application No. 10-2014-0078244 filed in the Korean Intellectual Property Office on Jun. 25, 2014, the entire contents of which are incorporated herein by reference.

### BACKGROUND

(a) Field

The present disclosure relates to a display device and a manufacturing method thereof. More particularly, the present disclosure relates to a display device that prevents a deterioration of a voltage holding ratio (VHR) by remaining liquid crystal, and a manufacturing method thereof.

(b) Description of the Related Art

A computer monitor, a television, a mobile phone, and the like that are widely used generally have a display device. Examples of such display device include a cathode ray tube display device, a liquid crystal display, and a plasma display device.

Liquid crystal displays are widely used as a type of flat panel display. A liquid crystal display generally has two display panels on which field generating electrodes such as pixel electrodes and a common electrode are formed, and a liquid crystal layer that is interposed between the panels. Voltages are applied to the field generating electrodes to generate electric fields in the liquid crystal layer at the pixel level. Because the alignments of the liquid crystal molecules of the liquid crystal layer are determined by the electric fields, the polarizations of incident light on the liquid crystal molecules can be controlled by manipulating the electric fields, thereby displaying an image.

The two display panels forming the liquid crystal display may be a thin film transistor array panel and an opposing display panel. In the thin film transistor array panel, a gate line transmitting a gate signal and a data line transmitting a data signal are formed to be crossed. A thin film transistor connected to the gate line and the data line and a pixel electrode connected to the thin film transistor may also be formed. The opposing display panel may include a light blocking member, a color filter, a common electrode, etc. In some cases, the light blocking member, the color filter, and the common electrode may be formed in the thin film transistor array panel.

Accordingly, because the constituent elements are respectively formed on the two substrates in the conventional liquid crystal display, the display device is heavy and costly and the processing time is long.

### SUMMARY

The present system and method provide a display device minimizing generation of remaining liquid crystal that may exist on an alignment layer and deterioration of a voltage holding ratio (VHR) that may be generated by the remaining liquid crystal by using an inorganic layer, and a manufacturing method thereof.

A display device according to an exemplary embodiment of the present system and method includes: a substrate including a plurality of pixel areas; a thin film transistor formed on the substrate; a first insulating layer formed on the thin film transistor; a pixel electrode connected to the thin film transistor and formed on the first insulating layer; a liquid crystal layer filling a microcavity formed on the pixel electrode; a common electrode separated from the pixel electrode by the microcavity; a second insulating layer and a roof layer formed on the common electrode; an injection hole formed on a side of the microcavity to expose a portion of the microcavity; an alignment layer formed inside the microcavity and on a surface of the injection hole; a third insulating layer formed on the roof layer; a blocking film formed at a position corresponding to the injection hole on the alignment layer; and an overcoat covering the injection hole to seal the microcavity and formed on the third insulating layer and the blocking film.

The third insulating layer and the blocking film may be formed of the same material, and the third insulating layer and the blocking film may be formed of an inorganic layer.

The third insulating layer and the blocking film may include at least one among silicon nitride (SiNx), silicon oxide (SiOx), and a silicon oxynitride (SiOxNy).

The blocking film may be formed to intrude into at least a portion of the microcavity.

The pixel electrode may include a first sub-pixel electrode and a second sub-pixel electrode positioned on opposite sides of where the injection hole is located, and the third insulating layer may be formed to a boundary of the first sub-pixel electrode and the second sub-pixel electrode.

A color filter formed under the first insulating layer at a position corresponding to the plurality of pixel areas, and a light blocking member formed under the first insulating layer at a position corresponding to the injection hole may be further included, and the blocking film may be formed at the position corresponding to the light blocking member.

The blocking film may be formed of an inorganic layer.

A method for manufacturing a display device according to another exemplary embodiment of the present system and method includes: forming a thin film transistor on a substrate; forming a first insulating layer on the thin film transistor; forming a pixel electrode connected to the thin film transistor on the first insulating layer; forming a sacrificial layer on the pixel electrode; forming a common electrode on the sacrificial layer; forming a second insulating layer on the common electrode; coating and patterning an organic material on the second insulating layer to form a roof layer; patterning the second insulating layer and the common electrode by using the roof layer as a mask to expose the sacrificial layer; removing the exposed sacrificial layer to form a microcavity between the pixel electrode and the common electrode and an injection hole; injecting an alignment material into the microcavity through the injection hole to form an alignment layer inside the microcavity and on a surface of the injection hole; forming a third insulating layer and a blocking film on a surface of the roof layer and the injection hole; injecting a liquid crystal material into the microcavity to form a liquid crystal layer; and forming an overcoat on the third insulating layer to seal the microcavity.

The third insulating layer and the blocking film may be simultaneously formed with the same material.

The third insulating layer and the blocking film may be formed by sputtering.

According to an exemplary embodiment of the present system and method, by manufacturing a display device using one substrate, weight, thickness, cost, and process time of the display device may be reduced.

Also, according to an exemplary embodiment of the present system and method, by using the inorganic layer, the generation of the remaining liquid crystal that may exist on the alignment layer may be minimized and the deterioration of the voltage holding ratio (VHR) due to the remaining liquid crystal may be prevented.

### BRIEF DESCRIPTION OF THE DRAWINGS

FIG. 1 is a top plan view of a display device according to an exemplary embodiment of the present system and method.

FIG. 2 is a top plan view of one pixel of a display device according to an exemplary embodiment of the present system and method.

FIG. 3 is a cross-sectional view taken along a line III-III of FIG. 1.

FIG. 4 is a cross-sectional view taken along a line IV-IV of FIG. 1.

FIG. 5, FIG. 6, FIG. 7, FIG. 8, and FIG. 9 are cross-sectional views that sequentially show a manufacturing method of a display device according to an exemplary embodiment of the present system and method.

FIG. 10 is a cross-sectional view of a display device according to another exemplary embodiment of the present system and method.

FIG. 11A, FIG. 11B, and FIG. 11C illustrate structures of a display device that have various voltage holding ratios.

### DETAILED DESCRIPTION OF THE EMBODIMENTS

The present system and method are described with reference to the accompanying drawings in which exemplary embodiments of the system and method are shown. Those of ordinary skill in the art would understand that the described embodiments may be modified in various different ways, all without departing from the spirit or scope of the present system and method.

In the drawings, the thickness of layers, films, panels, regions, etc., are exaggerated for clarity. Like reference numerals designate like elements throughout the specification. It is understood that when an element such as a layer, film, region, or substrate is referred to as being “on” another element, it can be directly on the other element or intervening elements may also be present. In contrast, when an element is referred to as being “directly on” another element, there are no intervening elements present.

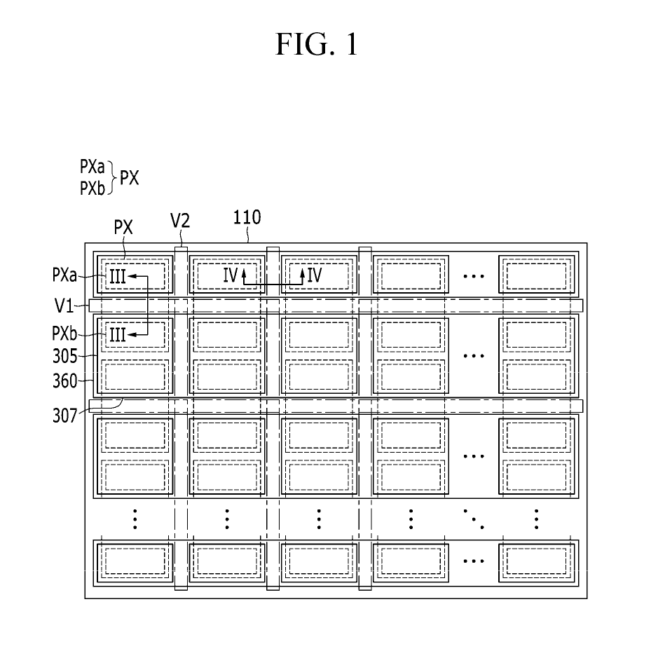

First, a display device according to an exemplary embodiment of the present system and method is described with reference to FIG. 1, which shows a top plan view of the display device. Referring to FIG. 1, the display device includes a substrate 110 that is made of a material such as glass or plastic, and a roof layer 360 formed on the substrate 110.

The substrate 110 includes a plurality of pixel areas PX. The plurality of pixel areas PX is disposed in a matrix form that includes a plurality of pixel rows and a plurality of pixel columns. Each of the pixel areas PX may include a first sub-pixel area PXa and a second sub-pixel area PXb. The first sub-pixel area PXa and the second sub-pixel area PXb may be disposed adjacent to each other in a pixel column direction. A first valley V1 is formed along a pixel row direction between the first sub-pixel area PXa and the second sub-pixel area PXb. A second valley V2 is formed between adjacent pixel columns and extends in the pixel column direction.

The roof layer 360 is formed to extend in the pixel row direction. An injection hole 307 is formed by removing the roof layer 360 in the first valley V1 so that constituent elements positioned under the roof layer 360 may be exposed to the outside. Adjacent roof layers 360 are separated by a first valley V1.

At least a portion of each of the roof layer 360 formed between adjacent second valleys V2 is spaced apart from the substrate 110 such that a microcavity 305 is formed. At least a portion of each of the roof layers 360 formed in the second valley V2 is attached to the substrate 110 such that both sides of the microcavity 305 are covered. That is, the microcavity 305 is enclosed by the roof layer 360 at its sides along adjacent second valleys V2.

The aforementioned structure of the display device according to the exemplary embodiment of the present system and method is merely an example. Various modifications are possible. For example, the disposition forms of the pixel area PX, the first valley V1, and the second valley V2 may be changed, the plurality of roof layers 360 may also be connected to each other in the first valley V1, and a part of the roof layer 360 formed in the second valley V2 may be spaced apart from the substrate 110 such that the adjacent microcavities 305 are connected to each other.

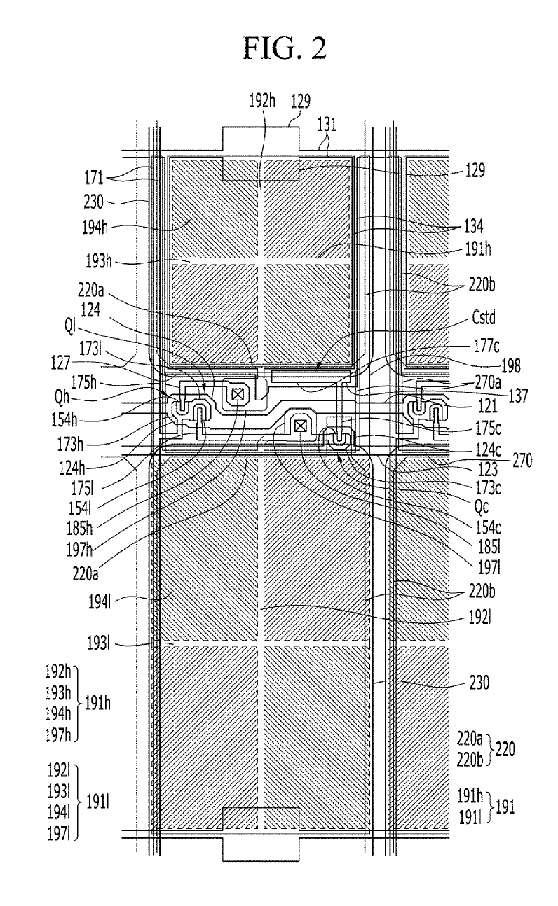

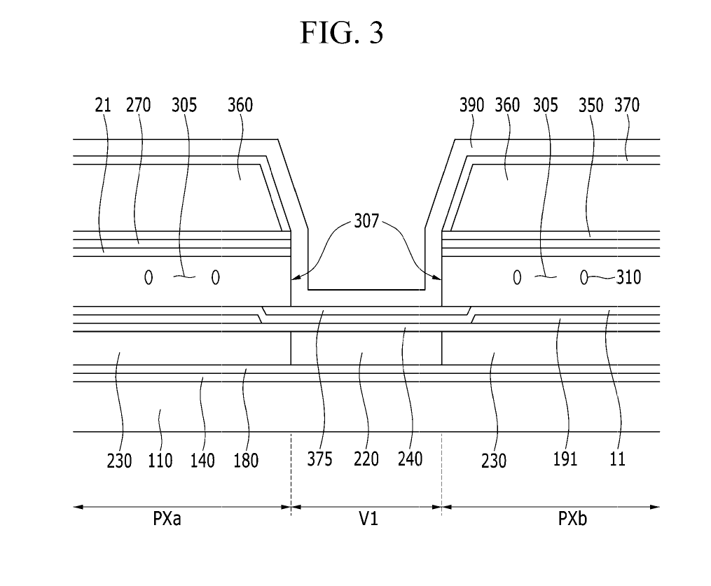

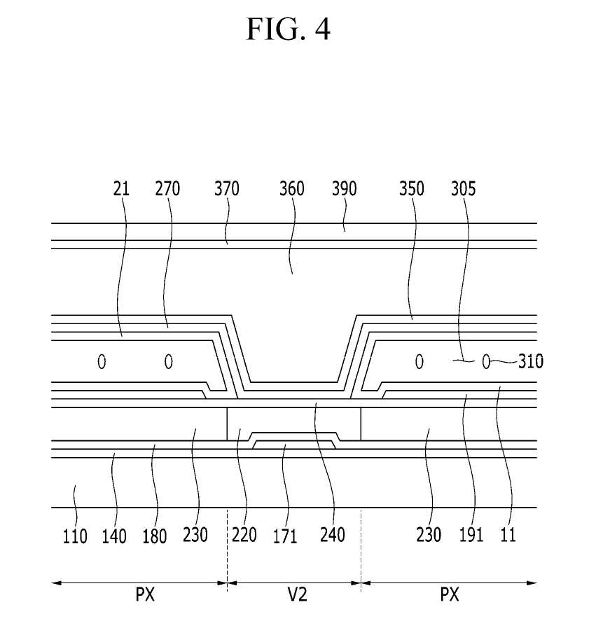

Next, one pixel of the display device according to an exemplary embodiment of the present system and method is described with reference to FIGS. 2 to 4 and FIG. 1. FIG. 2 is a top plan view of one pixel of a display device according to an exemplary embodiment of the present system and method. FIG. 3 is a cross-sectional view taken along a line III-III of FIG. 1. FIG. 4 is a cross-sectional view taken along a line IV-IV of FIG. 1.

Referring to FIG. 1 to FIG. 4, a plurality of gate conductors that includes a plurality of gate lines 121, a plurality of voltage step-down gate lines 123, and a plurality of storage electrode lines 131 is formed on the substrate 110.

The gate lines 121 and the voltage step-down gate lines 123 mainly extend in a horizontal direction and transmit gate signals. The gate conductors further include a first gate electrode 124h and a second gate electrode 124l that protrude laterally (e.g., upward and downward) from the gate line 121, and a third gate electrode 124c that protrudes laterally (e.g., upward, toward the nearest gate line 121) from the voltage step-down gate line 123. The first gate electrode 124h and the second gate electrode 124l are connected to each other and may be considered as one gate electrode. The shape of the protrusion of the first, second, and third gate electrodes 124h, 124l, and 124c may be modified.

The storage electrode line 131 mainly extends in the horizontal direction and transmits a predetermined voltage such as a common voltage Vcom. The storage electrode line 131 includes a storage electrode 129 that protrudes laterally (e.g., upward and downward) therefrom, a pair of vertical parts 134 that extends toward (e.g., downward) and substantially perpendicular to the gate line 121, and a horizontal part 127 that connects the ends of the pair of vertical parts 134. The horizontal part 127 includes a capacitive electrode 137 that extends toward (e.g., downwardly) the nearest step-down gate line 123.

A gate insulating layer 140 is formed on the gate conductors 121, 123, 124h, 124l, 124c, and 131. The gate insulating layer 140 may be formed of an inorganic insulating material such as a silicon nitride (SiNx) or a silicon oxide (SiOx). Further, the gate insulating layer 140 may be formed of a single layer or multilayers.

A first semiconductor 154h, a second semiconductor 154l, and a third semiconductor 154c are formed on the gate insulating layer 140. The first semiconductor 154h may be disposed on the first gate electrode 124h, the second semiconductor 154l may be disposed on the second gate electrode 124l, and the third semiconductor 154c may be disposed on the third gate electrode 124c. The first semiconductor 154h and the second semiconductor 154l may be connected to each other, and the second semiconductor 154l and the third semiconductor 154c may be connected to each other. Further, the first semiconductor 154h may be formed to extend below (e.g., overlap with) a data line 171. The first to third semiconductors 154h, 154l, and 154c may be formed of amorphous silicon, polycrystalline silicon, or a metal oxide.

Ohmic contacts (not illustrated) may be further formed on the first to third semiconductors 154h, 154l, and 154c, respectively. The ohmic contacts may be formed of a material such as a silicide or n+ hydrogenated amorphous silicon highly doped with an n-type impurity.

The data line 171 transmits a data signal and mainly extends in a vertical direction to intersect the gate line 121 and the voltage step-down gate line 123. Each data line 171 includes a first source electrode 173h and a second source electrode 173l that extend toward the first gate electrode 124h and the second gate electrode 124l and are connected to each other.

Each of a first drain electrode 175h, a second drain electrode 175l, and a third drain electrode 175c includes one wide end and another end having a rod shape. The rod-shaped ends of the first drain electrode 175h and the second drain electrode 175l are partially enclosed by the first source electrode 173h and the second source electrode 173l, respectively. The wide end of the second drain electrode 175l extends again to form a third source electrode 173c that has a U-shape. A wide end 177c of the third drain electrode 175c is superimposed with the capacitive electrode 137 to form a voltage step-down capacitor Cstd, and the rod-shaped end is partially enclosed by the third source electrode 173c.

The first gate electrode 124h, the first source electrode 173h, the first drain electrode 175h, and the first semiconductor 154h form a first thin film transistor Qh, the second gate electrode 124l, the second source electrode 173l, the second drain electrode 175l, and the second semiconductor 154l form a second thin film transistor Ql, and the third gate electrode 124c, the third source electrode 173c, the third drain electrode 175c, and the third semiconductor 154c form a third thin film transistor Qc.

The first semiconductor 154h, the second semiconductor 154l, and the third semiconductor 154c may be linearly connected to each other and have substantially the same planar shape as the data conductors 171, 173h, 173l, 173c, 175h, 175l, and 175c and the ohmic contacts therebelow, except at channel regions between the source electrodes 173h, 173l, and 173c and the drain electrodes 175h, 175l, and 175c.

The first semiconductor 154h has a portion that is not blocked by the first source electrode 173h and the first drain electrode 175h and positioned between the first source electrode 173h and the first drain electrode 175h to be exposed. The second semiconductor 154l has a portion that is not blocked by the second source electrode 173l and the second drain electrode 175l and positioned between the second source electrode 173l and the second drain electrode 175l to be exposed. The third semiconductor 154c has a portion that is not blocked by the third source electrode 173c and the third drain electrode 175c and positioned between the third source electrode 173c and the third drain electrode 175c to be exposed.

A passivation layer 180 is formed on the data conductors 171, 173h, 173l, 173c, 175h, 175l, and 175c and the semiconductors 154h, 154l, and 154c that have portions exposed between the source electrodes 173h/173l/173c and the drain electrodes 175h/175l/175c. The passivation layer 180 may be formed of an organic insulating material or an inorganic insulating material as a single layer or multilayers.

A color filter 230 is formed in the pixel area PX on the passivation layer 180. Each of the color filters 230 may represent one of three primary colors such as red, green, and blue. However, the color filter 230 is not limited to the three primary colors of red, green, and blue, and may represent cyan, magenta, yellow, and white. In an embodiment different from that shown in FIG. 3, the color filter 230 may extend longitudinally in the column direction between the adjacent data lines 171.

A light blocking member 220 is formed in a region between adjacent color filters 230. The light blocking member 220 may be formed at a border of the pixel areas PX and on the thin film transistor to prevent light leakage. The color filters 230 may be formed in the first sub-pixel area PXa and the second sub-pixel area PXb. The light blocking member 220 may be formed between the first sub-pixel area PXa and the second sub-pixel area PXb.

The light blocking member 220 includes a horizontal light blocking member 220a that extends along the gate line 121 and the voltage step-down gate line 123 to vertically expand and cover a region where the first thin film transistor Qh, the second thin film transistor Ql, and the third thin film transistor Qc are disposed. The light blocking member 220 also includes a vertical light blocking member 220b that extends along the data line 171. That is, the horizontal light blocking member 220a may be formed in the first valley V1 and the vertical light blocking member 220b may be formed in the second valley V2. The color filter 230 and the light blocking member 220 may overlap with each other in some regions.

A first insulating layer 240 may be further formed on the color filter 230 and the light blocking member 220. The first insulating layer 240 may be formed of an inorganic insulating material such as a silicon nitride (SiNx), a silicon oxide (SiOx), or a silicon oxynitride (SiOxNy). A function of the first insulating layer 240 is to protect the color filter 230 and the light blocking member 220 that are formed of an organic material. The first insulating layer 240 may be omitted in some cases.

A plurality of first contact holes 185h and a plurality of second contact holes 185l are formed in the first insulating layer 240, the light blocking member 220, and the passivation layer 180 to expose the wide end of the first drain electrode 175h and the wide end of the second drain electrode 175l, respectively.

A pixel electrode 191 is formed on the first insulating layer 240. The pixel electrode 191 is connected to a common electrode 270 that is disposed in a pixel area adjacent thereto in a row direction or a column direction, and a predetermined voltage is applied thereto.

The pixel electrode 191 includes a first sub-pixel electrode 191h and a second sub-pixel electrode 191l that are separated with the gate line 121 and the voltage step-down gate line 123 therebetween and disposed in a first portion and a second portion of the pixel area PX. The first and second portions of the pixel area PX lie on opposite sides of the gate line 121 and the voltage step-down gate line 123 and adjacent to each other in a column direction. That is, the first sub-pixel electrode 191h and the second sub-pixel electrode 191l are separated from each other with the first valley V1 therebetween, and the first sub-pixel electrode 191h is disposed in the first sub-pixel area PXa and the second sub-pixel electrode 191l is disposed in the second sub-pixel area PXb.

The first sub-pixel electrode 191h and the second sub-pixel electrode 191l are connected to the first drain electrode 175h and the second drain electrode 175l through the first contact hole 185h and the second contact hole 185l, respectively. Accordingly, when the first thin film transistor Qh and the second thin film transistor Q1 are turned on, a data voltage is applied to the first sub-pixel electrode 191h and the second sub-pixel electrode 191l from the first drain electrode 175h and the second drain electrode 175l.

In the embodiment shown in FIG. 2, an overall shape of each of the first sub-pixel electrode 191h and the second sub-pixel electrode 191l is a quadrangle, and the first sub-pixel electrode 191h and the second sub-pixel electrode 191l include cross-shaped stem parts that include horizontal stem parts 193h and 193l and vertical stem parts 192h and 192l that intersect the horizontal stem parts 193h and 193l, respectively. Further, the first sub-pixel electrode 191h and the second sub-pixel electrode 191l include a plurality of minute branch parts 194h and 194l and protrusions 197h and 197l that protrude laterally from the edges of the sub-pixel electrodes 191h and 191l, respectively.

Each of the sub-pixel electrodes 191 is divided into four sub-regions by the horizontal stem parts 193h and 193l and the vertical stem parts 192h and 192l, respectively. The minute branch parts 194h and 194l extend obliquely from the horizontal stem parts 193h and 193l and the vertical stem parts 192h and 192l. The extending direction may form approximately 45 degrees or 135 degrees with the gate line 121 or the horizontal stem parts 193h and 193l. Further, the extending directions of the minute branch parts 194h and 194l in two adjacent sub-regions may be perpendicular to each other.

In the exemplary embodiment of FIG. 2, the first sub-pixel electrode 191h further includes an outer peripheral stem part that encloses the outer periphery. The second sub-pixel electrode 191l further includes horizontal parts that are disposed in an upper end and a lower end and left and right vertical parts 198 that are disposed at the left and the right of the first sub-pixel electrode 191h. The left and right vertical parts 198 may prevent capacitive coupling between the data line 171 and the first sub-pixel electrode 191h.

The shape of the pixel area, the structure of the thin film transistor, and the shape of the pixel electrode described above are provided as examples. The present system and method are not limited to these examples and may be varied.

The common electrode 270 is formed on the pixel electrode 191 but separated from the pixel electrode 191 by a predetermined distance. The microcavity 305 is formed between the pixel electrode 191 and the common electrode 270. That is, the microcavity 305 is enclosed by the pixel electrode 191 and the common electrode 270. The width and area of the microcavity 200 may be variously changed depending on the size and resolution of the display device.

The common electrode 270 may be formed of a transparent metal material such as indium-tin oxide (ITO) and indium-zinc oxide (IZO). A predetermined voltage may be applied to the common electrode 270 such that an electric field is generated between the pixel electrode 191 and the common electrode 270.

A first alignment layer 11 is formed on the pixel electrode 191. The first alignment layer 11 may also be formed directly on the first insulating layer 240 in areas not covered by the pixel electrode 191.

The first insulating layer 240 may be omitted in some cases. In such cases, the first alignment layer 11 may be formed directly on the color filter 230 and the light blocking member 220 in areas not covered by the pixel electrode 191.

A second alignment layer 21 is formed below the common electrode 270 and faces the first alignment layer 11. The first alignment layer 11 and the second alignment layer 21 may be formed as vertical alignment layers using an alignment material such as polyamic acid, polysiloxane, or polyimide. The first and second alignment layers 11 and 21 may be connected to each other at an edge of the pixel area PX.

A liquid crystal layer that is formed of liquid crystal molecules 310 is formed in the microcavity 305 disposed between the pixel electrode 191 and the common electrode 270. The liquid crystal molecules 310 may have negative dielectric anisotropy. That is, when no electric field is applied, the liquid crystal molecules 310 may be aligned in a direction perpendicular to the substrate 110 and a vertical orientation may be generated.

The first sub-pixel electrode 191h and the second sub-pixel electrode 191l to which the data voltage is applied generate an electric field together with the common electrode 270 so as to determine an orientation of the liquid crystal molecules 310 disposed in the microcavity 305 between the electrodes 191 and 270. The luminance of the light passing through the liquid crystal layer may vary depending on the orientation of the liquid crystal molecules 310 determined as described above.

A second insulating layer 350 may be further formed on the common electrode 270. The second insulating layer 350 may be made of an inorganic insulating material such as a silicon nitride (SiNx), a silicon oxide (SiOx), and a silicon oxynitride (SiOxNy), and may be omitted if necessary.

The roof layer 360 is formed on the second insulating layer 350 above the microcavity 350. The roof layer 360 may be made of an organic material. The roof layer 360 is hardened by a curing process to maintain the shape of the microcavity 305. That is, the roof layer 360 is formed to be spaced apart from the pixel electrode 191 with the microcavity 305 therebetween.

The roof layer 360 is formed in each pixel area PX and second valley V2 along a pixel row but not in the first valley V1. That is, the roof layer 360 is not formed between the first sub-pixel area PXa and the second sub-pixel area PXb. The microcavity 305 is formed below each roof layer 360 at each of the first sub-pixel area PXa and the second sub-pixel area PXb. In the second valley V2, the microcavity 305 is not formed below the roof layer 360; instead, the roof layer 360 is formed to be attached to the substrate 110. Accordingly, a thickness of the roof layer 360 positioned at the second valley V2 may be larger than a thickness of the roof layer 360 positioned at each of the first sub-pixel area PXa and the second sub-pixel area PXb. The upper surface and both sides of the microcavity 305 are covered by the roof layer 360.

The roof layers 360 are not positioned in the first valley region such that they are separated from each other with the first valley region therebetween. As a result, the roof layer 360 in a region adjacent to the valley region has an inclined surface.

The injection hole 307 exposing a part of the microcavity 305 is formed in the common electrode 270, the second insulating layer 350, and the roof layer 360. The injection holes 307 may be formed at the edges of the first sub-pixel area PXa and the second sub-pixel area PXb that face each other. That is, the injection holes 307 may be formed to correspond to the lower side of the first sub-pixel area PXa and the upper side of the second sub-pixel area PXb so as to expose a side of each of the adjacent microcavities 305. Since the microcavity 305 is exposed by the injection hole 307, an aligning agent, a liquid crystal material, or the like may be injected into the microcavity 305 through the injection hole 307.

A third insulating layer 370 is formed on the roof layer 360 and the alignment layer 11 in areas not covered by the roof layer. The third insulating layer 370 may be made of an inorganic insulating material such as a silicon nitride (SiNx), a silicon oxide (SiOx), and a silicon oxynitride (SiOxNy).

According to an exemplary embodiment of the present system and method, the third insulating layer 370 is formed on the alignment layer 11 in areas not covered by the roof layer 360, such as in the first valley V1, as a blocking film 375. Portions of the blocking film 375 may further extend into the adjacent microcavities 305 such that the portions overlap with the injection hole 307 and the roof layer 360, such as shown in FIG. 3. That is, the portion of the blocking film 375 that corresponds to the location of injection hole 307 is formed of the same material as the third insulating layer 370 and may further extend toward the microcavity 305 such that the boundary of the blocking film 375 intersects or coincides with the boundary of the pixel electrode 191 formed inside the microcavity 305.

If the blocking film 375 is not formed at the injection hole 307 and the alignment layer 11 is exposed directly, remnants of liquid crystal left on the alignment layer 11 from when the liquid crystal is injected into the microcavity 305 may cause deterioration of the voltage holding ratio (VHR) of the display device at a subsequent time. Accordingly, by forming the blocking film 375 on the alignment layer 11 at the injection hole 307 using the same material as the third insulating layer 370 formed on the roof layer 360, the deterioration of the voltage holding ratio by the remaining liquid crystal may be prevented. That is, compared with the case in which the blocking film 375 is not formed, the remaining liquid crystal that may exist at the upper surface of the injection hole 307 may be further removed by forming the blocking film 375.

Also, when the first insulating layer 240 is omitted in some cases, contamination of the liquid crystal layer by the remaining material that may be generated in the light blocking member 220 positioned under the alignment layer 11 may be prevented by the blocking film 375 formed at the injection hole 307.

An overcoat 390 may be formed on the third insulating layer 370 and the blocking film 375. The overcoat 390 is formed to cover the injection hole 307 exposing the part of the microcavity 305 to the outside. That is, the overcoat 390 may seal the microcavity 305 so that the liquid crystal molecules 310 formed in the microcavity 305 are not discharged to the outside. Since the overcoat 390 contacts the liquid crystal molecules 310, the overcoat 390 may be made of a material that does not react with liquid crystal molecules 310. For example, the overcoat 390 may be made of parylene and the like.

The overcoat 390 may be formed as multilayers such as double layers and triple layers. In the case of double layer, two layers may be made of different materials. For example, the overcoat 390 may include a layer made of an organic insulating material and a layer made of an inorganic insulating material. In the case of triple layers, materials of adjacent layers in the three layers may be different from each other.

Although not illustrated, polarizers may be further formed on the upper and lower surfaces of the display device. The polarizers may be include a first polarizer and a second polarizer. The first polarizer may be attached onto the lower surface of the substrate 110, and the second polarizer may be attached onto the overcoat 390.

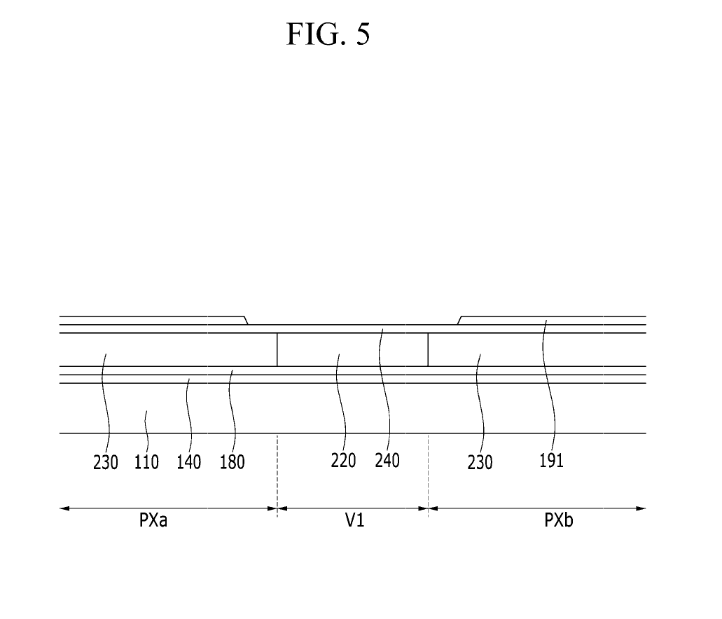

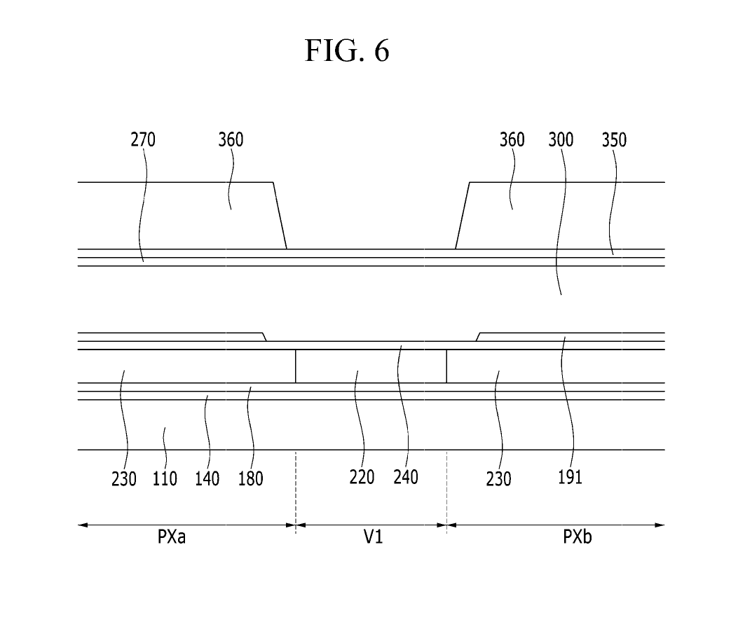

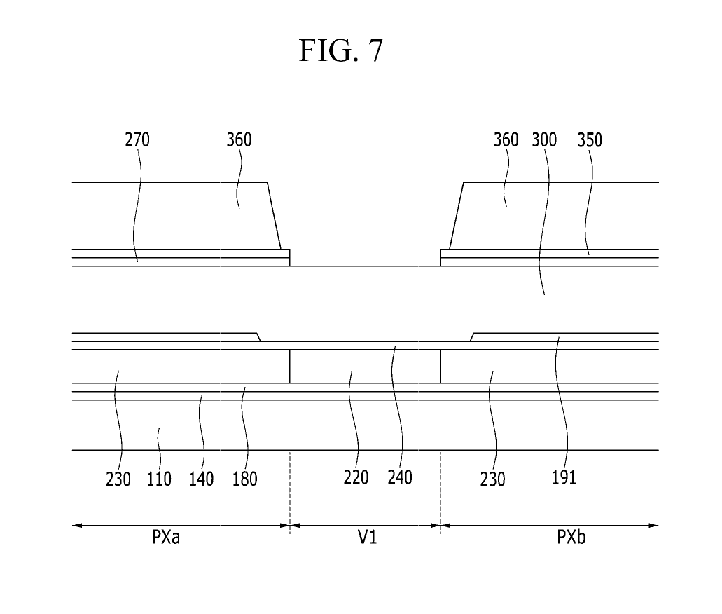

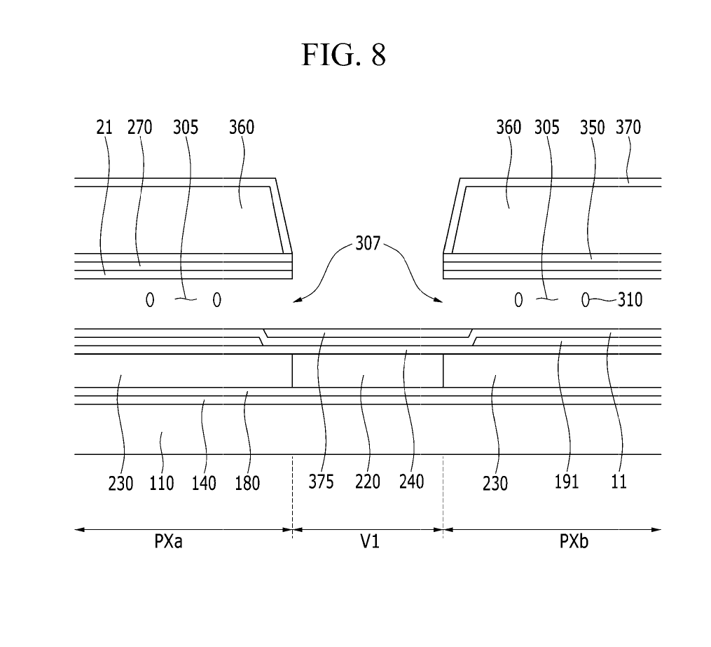

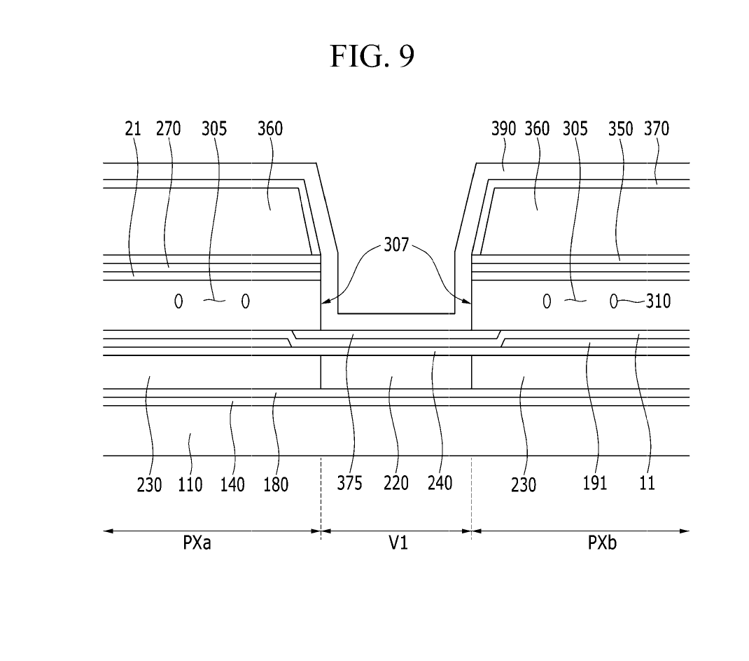

Next, a manufacturing method of the display device according to an exemplary embodiment of the present system and method is described below with reference mainly to FIG. 5 to FIG. 9 and some reference to FIG. 1 to FIG. 4. FIG. 5 to FIG. 9 are cross-sectional views that sequentially show a manufacturing method of a display device according to an exemplary embodiment of the present system and method.

As illustrated in FIG. 5, a gate line 121 and a step-down gate line 123 extending in one direction are formed on an insulation substrate 110 that may be made of, for example, glass or plastic. A first gate electrode 124h, a second gate electrode 124l, and a third gate electrode 124c protruding from the gate line 121 are also formed.

Further, a storage electrode line 131 may be formed so as to be spaced apart from the gate line 121, the step-down gate line 123, and the first to third gate electrodes 124h, 124l, and 124c.

Next, a gate insulating layer 140 is formed on the substrate 110, the gate line 121, the step-down gate line 123, the first to third gate electrodes 124h, 124l, and 124c, and the storage electrode line 131. The gate insulating layer 140 may be formed as a single layer or multilayers and using an inorganic insulating material such as a silicon oxide (SiOx) or a silicon nitride (SiNx).

Next, a first semiconductor 154h, a second semiconductor 154l, and a third semiconductor 154c are formed by depositing and then patterning a semiconductor material, such as amorphous silicon, polycrystalline silicon, and a metal oxide, on the gate insulating layer 140. The first semiconductor 154h may be positioned on the first gate electrode 124h, the second semiconductor 154l may be positioned on the second gate electrode 124l, and the third semiconductor 154c may be positioned on the third gate electrode 124c.

Next, a data line 171 extending in the other direction is formed by depositing and then patterning a metal material. The metal material may be formed as a single layer or multilayers.

A first source electrode 173h protruding from the data line 171 and overlapping the first gate electrode 124h and a first drain electrode 175h spaced apart from the first source electrode 173h are formed together. A second source electrode 173l connected with the first source electrode 173h and a second drain electrode 175l spaced apart from the second source electrode 173l are formed together. A third source electrode 173c extending from the second drain electrode 175l and a third drain electrode 175c spaced apart from the third source electrode 173c are formed together.

The first to third semiconductors 154h, 154l, and 154c, the data line 171, the first to third source electrodes 173h, 173l, and 173c, and the first to third drain electrodes 175h, 175l, and 175c may be formed by sequentially depositing and then simultaneously patterning a semiconductor material and a metal material. In this case, the first semiconductor 154h may extend to the lower portion of the data line 171.

The first/second/third gate electrodes 124h/124l/124c, the first/second/third source electrodes 173h/173l/173c, and the first/second/third drain electrodes 175h/175l/175c form first/second/third thin film transistors (TFTs) Qh/Q1/Qc together with the first/second/third semiconductors 154h/154l/154c, respectively.

Next, a passivation layer 180 is formed on the data line 171, the first to third source electrodes 173h, 173l, and 173c, the first to third drain electrodes 175h, 175l, and 175c, and the semiconductors 154h, 154l, and 154c exposed between the respective source electrodes 173h/173l/173c and the respective drain electrodes 175h/175l/175c. The passivation layer 180 may be made of an organic insulating material or an inorganic insulating material and formed as a single layer or multilayers.

Next, a color filter 230 is formed in each pixel area PX on the passivation layer 180. The color filter 230 is formed in the first sub-pixel area PXa and the second sub-pixel area PXb and may or may not be formed in the first valley V1. Further, color filters 230 having the same color may be formed in a column direction of the plurality of pixel areas PX. In the case of forming color filters 230 having three colors, a first colored color filter 230 may be first formed and then a second colored color filter 230 may be formed by shifting a mask. Next, a third colored color filter may be formed by shifting a mask.

A light blocking member 220 is then formed on the boundary of each pixel area PX on the passivation layer 180 and the thin film transistor. The light blocking member 220 may also be formed at the first valley V1 positioned between the first sub-pixel area PXa and the second sub-pixel area PXb.

Next, a first insulating layer 240 made of an inorganic insulating material such as a silicon nitride (SiNx), a silicon oxide (SiOx), and a silicon oxynitride (SiOxNy) is formed on the color filter 230 and the light blocking member 220.

In the above exemplary embodiment, after forming the color filter 230 and forming the light blocking member 220, the first insulating layer 240 is formed. The present system and method, however, are not limited to this sequence. For example, the color filter 230 may be formed after forming the light blocking member 220, and the light blocking member 220 may be formed after forming the color filter 230 and the first insulating layer 240.

Next, a first contact hole 185h is formed by etching the passivation layer 180, the light blocking member 220, and the first insulating layer 240 so as to expose a part of the first drain electrode 175h. A second contact hole 185l is also formed so as to expose a part of the second drain electrode 175l.

Subsequently, a first sub-pixel electrode 191h is formed in the first sub-pixel area PXa and a second sub-pixel electrode 191l is formed in the second sub-pixel area PXb by depositing and then patterning a transparent metal material such as indium tin oxide (ITO) and indium zinc oxide (IZO) on the first insulating layer 240. The first sub-pixel electrode 191h and the second sub-pixel electrode 191l may be separated from each other with the first valley V1 therebetween. The first sub-pixel electrode 191h is connected with the first drain electrode 175h through the first contact hole 185h. The second sub-pixel electrode 191l is connected to the second drain electrode 175l through the second contact hole 185l.

Horizontal stem parts 193h and 193l and vertical stem parts 192h and 192l that cross the horizontal stem parts 193h and 193l are formed in the first sub-pixel electrode 191h and the second sub-pixel electrode 191l, respectively. Further, a plurality of minute branch parts 194h and 194l that extend obliquely from the horizontal stem parts 193h and 193l and the vertical stem parts 192h and 192l are formed.

As illustrated in FIG. 6, a sacrificial layer 300 is formed by coating a photosensitive organic material on the pixel electrode 191 and performing a photolithography process. The sacrificial layers 300 are formed to be connected to each other along the plurality of pixel columns. That is, the sacrificial layer 300 is formed to cover each pixel area PX, as well as the first valley V1 positioned between the first sub-pixel area PXa and the second sub-pixel area PXb.

Next, a common electrode 270 is formed by depositing a transparent metal material, such as indium tin oxide (ITO) and indium zinc oxide (IZO), on the sacrificial layer 300. A second insulating layer 350 formed of an inorganic insulating material, such as a silicon nitride (SiNx), a silicon oxide (SiOx), and a silicon oxynitride (SiOxNy), may then be formed on the common electrode 270.

Next, the roof layer 360 is formed by coating and patterning an organic material on the second insulating layer 350. In this case, the organic material positioned at the first valley V1 may be patterned so as to be removed. As a result, a plurality of roof layers 360 adjacent to each other in the column direction and extending in the row direction may be formed. Each of the plurality of roof layers 360 may overlap with pixels in adjacent pixel rows.

As illustrated in FIG. 7, the second insulating layer 350 and the common electrode 270 are then patterned using the roof layer 360 as a mask. For example, the second insulating layer 350 is dry-etched by using the roof layer 360 as a mask, and then the common electrode 270 is wet-etched.

As illustrated in FIG. 8, the sacrificial layer 300 is fully removed, such as by applying a developer and a stripper solution on the substrate 110 where the sacrificial layer 300 is exposed or by using an ashing process. When the sacrificial layer 300 is removed, the microcavity 305 is formed in the space where the sacrificial layer 300 was previously present.

The pixel electrode 191 and the common electrode 270 are spaced apart from each other with the microcavity 305 therebetween. The pixel electrode 191 and the roof layer 360 are also spaced apart from each other with the microcavity 305 therebetween. The common electrode 270 and the roof layer 360 are formed to cover the upper surface and the sides of the microcavity 305 that does not contain an injection hole 307.

The injection hole 307 includes a portion where the roof layer 360, the second insulation layer 350, and the common electrode 270 are removed to expose the microcavity 305 to the outside. The injection hole 307 is formed along the first valley V1. For example, the injection holes 307 may be formed at the edges of the first sub-pixel area PXa and the second sub-pixel area PXb that face each other. That is, the injection holes 307 may correspond to the lower side of the first sub-pixel area PXa and the upper side of the second sub-pixel area PXb to expose a side of the microcavity 305 in each of the sub-pixel areas. In an another embodiment, the injection hole 307 may be formed along the second valley V2.

Next, the roof layer 360 is cured by applying heat to the substrate 110. This hardens the roof layer 360 so that it is able to maintain the shape of the microcavity 305.

Next, an aligning agent containing an alignment material is deposited on the substrate 110 by a spin coating method or an inkjet method so that the aligning agent is injected into the microcavity 305 through the injection hole 307. After the aligning agent is injected into the microcavity 305, a curing process is performed such that a solution component is evaporated and the alignment material remains on the inner walls of the microcavity 305. That is, the first alignment layer 11 may be formed on the pixel electrode 191, and the second alignment layer 21 may be formed below the common electrode 270. The first alignment layer 11 and the second alignment layer 21 face each other with the microcavity 305 therebetween, and are connected to each other at an edge of the pixel area PX (i.e., side wall of the microcavity 305 may also be coated by the alignment material).

In this case, the first and second alignment layers 11 and 21 may be aligned in a direction perpendicular to the substrate 110, except at the side of the microcavity 305. In addition, a process of irradiating UV rays to the first and second alignment layers 11 and 21 may performed so that the first and second alignment layers 11 and 21 may be aligned in a direction parallel to the substrate 110.

According to an exemplary embodiment of the present system and method, after forming the first and second alignment layers 11 and 21, the third insulating layer 370 and the blocking film 375 may be simultaneously formed on the roof layer 360 using an inorganic insulating material such as a silicon nitride (SiNx), a silicon oxide (SiOx), or a silicon oxynitride (SiOxNy). Particularly, the third insulating layer 370 may be formed on the alignment layer 11 as the blocking film 375, wherein portions of the blocking film 375 overlap the injection hole 307 of the first valley region V1 (where the roof layer 360 is not formed), and on the roof layer 360. That is, the blocking film 375 positioned at the portion corresponding to the injection hole 307 may be formed of the same material as the third insulating layer 370.

The blocking film 375 formed at the injection hole 307 may be formed to intrude into at least a portion of the microcavity 305 near the injection hole 307. For example, as FIG. 8 shows, the blocking film 375 may be formed to extend to the boundary of the pixel electrode 191 inside the microcavity 305.

According to an exemplary embodiment, the third insulating layer 370 and the blocking film 375 are formed by sputtering, but the present system and method are not limited thereto. If the third insulating layer 370 and the blocking film 375 are not to be formed on the entire inner surface inside the microcavity 305, a deposition method, such as chemical vapor deposition (CVD), may be used to form the third insulating layer 370 on the injection hole 307 region and the roof layer 360.

When the blocking film 375 is not formed at the injection hole 307 and the alignment layer 11 is directly exposed, remnants of liquid crystal left on the alignment layer 11 from when the liquid crystal is injected into the microcavity 305 may cause deterioration of the voltage holding ratio (VHR) of the display device at a subsequent time. Accordingly, by forming the blocking film 375 on the alignment layer 11 at the injection hole 307 using the same material as the third insulating layer 370 on the roof layer 360, the deterioration of the voltage holding ratio by the remaining liquid crystal may be prevented. That is, compared with the case in which the blocking film 375 is not formed on the upper surface of the injection hole 307, the remaining liquid crystal that may exist at the upper surface of the injection hole 307 may be further removed by forming the blocking film 370.

Also, when the first insulating layer 240 is omitted in some cases, contamination of the liquid crystal layer by the remaining material that may be generated in the light blocking member 220 positioned under the alignment layer 11 may be prevented by forming the blocking film 375 at the injection hole 307.

The third insulating layer 370 may be formed to cover the upper surface and the side of the roof layer 360 to protect the roof layer 360. That is, when forming the third insulating layer 370, the pattern of the third insulating layer 370 for the roof layer 360 may be positioned at the outside of the pattern of the roof layer 360 so that the pattern of the third insulating layer 370 encompasses the roof layer 360.

The pattern of the second insulating layer 350 may be the same as the pattern of the third insulating layer 370 on the roof layer 360, or the pattern of the second insulating layer 350 may be formed inside of the pattern of the roof layer 360. In this case, the third insulating layer 370 on the roof layer 360 may be formed to contact the second insulating layer 350.

Also, the third insulating layer 370 on the roof layer 360 may be formed to enclose at least a portion of the end of the roof layer 360, the second insulating layer 350, the common electrode 270, and the second alignment layer 21 near the injection hole 307.

Next, when the liquid crystal material that includes liquid crystal molecules 310 is deposited on the substrate 110, such as by an inkjet method or a dispensing method, the liquid crystal material is injected into the microcavity 305 through the injection hole 307. According to one embodiment, the liquid crystal material may be deposited in the injection holes 307 formed along the odd-numbered first valleys V1 and not in the injection holes 307 formed along the even-numbered first valleys V1. In another embodiment, the liquid crystal material may be deposited in the injection holes 307 formed along the even-numbered first valleys V1 and not in the injection holes 307 formed along the odd-numbered first valleys V1.

When the liquid crystal material is deposited in the injection holes 307 formed along the odd-numbered first valleys V1, the liquid crystal material passes through the injection hole 307 by capillary force to be injected into the microcavity 305. In this case, the liquid crystal material is injected into the microcavity 305 by discharging air from the microcavity 305 through the injection holes 307 formed along the even-numbered first valleys V1.

According to another embodiment, the liquid crystal material may be deposited in all of the injection holes 307. That is, the liquid crystal material may be deposited in the injection holes 307 formed both along the odd-numbered first valleys V1 and the injection holes 307 formed along the even-numbered first valleys V1.

As described above, when the liquid crystal material is injected into the microcavity 305 by capillary force, the liquid crystal deposited in the injection hole 307 may contact a part of the roof layer 360 and remain on the roof layer 360 and the injection hole 307. However, when the third insulating layer 370 and the blocking film 375 are formed on the roof layer 360 and on the first alignment layer 11 exposed at the injection hole 307, according to an exemplary embodiment of the present system and method, the remaining liquid crystal that may exist on the roof layer 360 and the injection hole 307 may be reduced by a cleaning process of the remaining liquid crystal, thereby preventing the deterioration of the voltage holding ratio.

As shown in FIG. 9, an overcoat 390 is formed by depositing a material that does not react with the liquid crystal molecules 310 on the third insulating layer 370 and the blocking film 375. The overcoat 390 is formed to cover the injection hole 307 where the microcavity 305 is exposed to the outside, thereby sealing the microcavity 305.

Next, although not illustrated, polarizers may be further attached onto the upper and lower surfaces of the display device. The polarizers may include a first polarizer and a second polarizer. The first polarizer may be attached onto the lower surface of the substrate 110, and the second polarizer may be attached onto the overcoat 390.

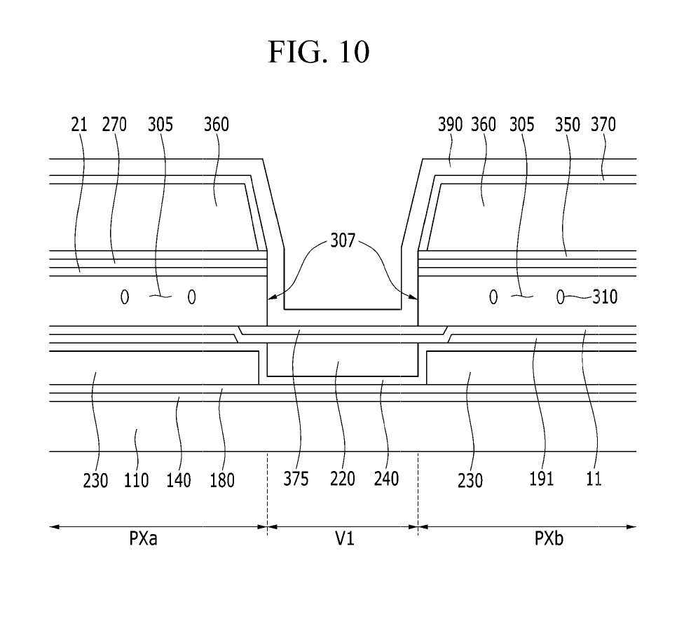

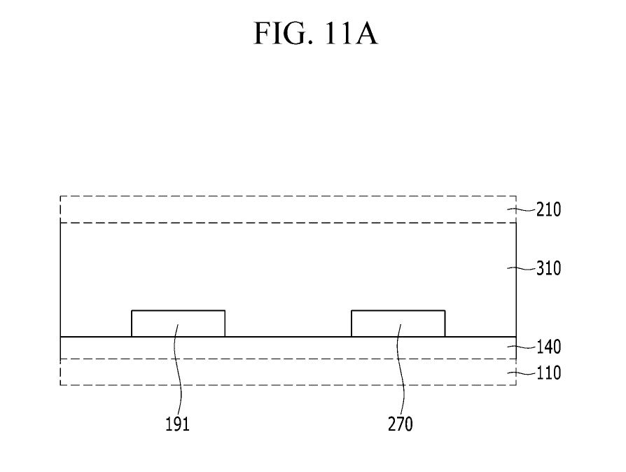

Now, a display device according to another exemplary embodiment of the present system and method is described with reference to FIG. 10. Hereafter, the constituent elements already described above are omitted, but constituent elements that are different from the described constituent elements are described.

Referring to FIG. 10, in a display device according to another exemplary embodiment of the present system and method, the first insulating layer 240 is formed on the color filter 230 at the position corresponding to the color filter 230 and under the light blocking member 220 at the position corresponding to the light blocking member 220. In this embodiment, although the first insulating layer 240 is not formed on the light blocking member 220, the blocking film 375 is still formed to overlap the light blocking member 220 so that contamination of the liquid crystal layer by the remaining material that may be generated in the light blocking member 220 may be prevented.

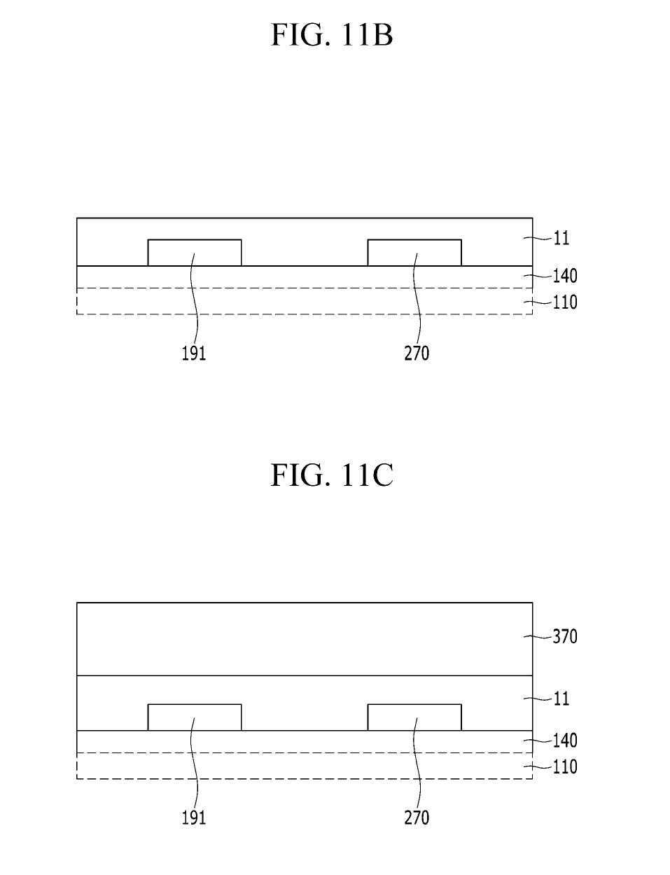

Next, various structures of a display device are described with reference to FIG. 11A to FIG. 11C. FIGS. 11A to 11C illustrate different structures of a display device that have various voltage holding ratios.

FIG. 11A shows a structure in which no alignment layer is formed. FIG. 11B shows a comparative example in which only the alignment layer is formed on the electrode (i.e., blocking film not formed). FIG. 11C shows a structure in which the inorganic insulating layer (i.e., blocking film) is formed on the alignment layer, according to an exemplary embodiment of the present system and method.

As shown in FIG. 11A to FIG. 11C, the gate insulating layer 140 is formed on the lower substrate 110, where the pixel electrode 191 and the common electrode 270 are formed to be separated by a predetermined distance. In the case of FIG. 11A, the liquid crystal molecules 310 are formed directly between the lower substrate 110 and the upper substrate 210 (i.e., no alignment layer is formed on the electrodes 191 and 270). In the case of FIG. 11B, the alignment layer 11 is formed on the electrodes 191 and 270. In the case of FIG. 11C, the inorganic insulating layer 370 is additionally formed on the alignment layer 11.

Example measurements of the voltage holding ratio for each of the three cases shown in FIG. 11A to FIG. 11C are represented in Table 1 to Table 3.

TABLE 1

| | Distance (μm) | Voltage holding ratio (%) |
|---|---|---|
| Example Structure of FIG. 1 | 3.5 | 59.3 |
| | 5.5 | 68.98 |
| | 7.5 | 78.52 |
| | 9.5 | 80.4 |

TABLE 2

| | Distance (μm) | Voltage holding ratio (%) |
|---|---|---|
| Example Structure of FIG. 2 | 3.5 | 0.01 |
| | 5.5 | 0.02 |
| | 7.5 | 55.4 |
| | 9.5 | 54.09 |

TABLE 3

| | Distance (μm) | Voltage holding ratio (%) |
|---|---|---|
| Example Structure of FIG. 3 | 3.5 | 54.48 |
| | 5.5 | 65.02 |
| | 7.5 | 79.86 |
| | 9.5 | 81.32 |

In Table 1 to Table 3, the distance represents a distance between the pixel electrode 191 and the common electrode 270. As shown in Table 1 to Table 3, in the case in which the alignment layer 11 is formed on the electrodes 191 and 270 (FIG. 2), the voltage holding ratio is decreased compared with the example structure of FIG. 1. In the case in which the insulating layer 370 is additionally formed on the inorganic alignment layer 11, the voltage holding ratio is maintained to a similar degree as the example structure of FIG. 1.

Therefore, according to the exemplary embodiment of the present system and method shown in FIG. 13, by using the inorganic layer, the generation of the remaining liquid crystal that may exist on the alignment layer is minimized, and the deterioration of the voltage holding ratio (VHR) generation by the remaining liquid crystal is prevented.

While the present system and method have been described in connection with exemplary embodiments, it is understood that the present system and method are not limited to the disclosed embodiments.

### DESCRIPTION OF SYMBOLS

| | |
|---|---|
| 11: first alignment layer | 21: second alignment layer |
| 110: substrate | 390: overcoat |
| 121: gate line | 123: step-down gate line |
| 124h: first gate electrode | 124l: second gate electrode |
| 124c: third gate electrode | 131: storage electrode line |
| 140: gate insulating layer | 154h: first semiconductor |
| 154l: second semiconductor | 154c: third semiconductor |
| 171: data line | 173h: first source electrode |
| 173l: second source electrode | 173c: third source electrode |
| 175h: first drain electrode | 175l: second drain electrode |
| 175c: third drain electrode | 180: passivation layer |
| 191: pixel electrode | 191h: first sub-pixel electrode |
| 191l: second sub-pixel electrode | 220: light blocking member |
| 230: color filter | 240: first insulating layer |
| 270: common electrode | 300: sacrificial layer |
| 305: microcavity | 307: injection hole |
| 310: liquid crystal molecule | 360: roof layer |
| 350: second insulating layer | 370: third insulating layer |

What is claimed is:

1. A display device comprising:
a substrate including a plurality of pixel areas;
a thin film transistor formed on the substrate;
a first insulating layer formed on the thin film transistor;
a pixel electrode connected to the thin film transistor and formed on the first insulating layer;
a liquid crystal layer filling a microcavity formed on the pixel electrode;
a common electrode separated from the pixel electrode by the microcavity;
a second insulating layer and a roof layer formed on the common electrode;
an injection hole formed on a side of the microcavity to expose a portion of the microcavity;
an alignment layer formed inside the microcavity and on a surface of the injection hole;
a third insulating layer formed on the roof layer;
a blocking film formed at a position corresponding to the injection hole on the alignment layer; and
an overcoat covering the injection hole to seal the microcavity and formed on the third insulating layer and the blocking film.

2. The display device of claim 1, wherein
the third insulating layer and the blocking film are formed of the same material, and
the third insulating layer and the blocking film are formed of an inorganic layer.

3. The display device of claim 2, wherein
the third insulating layer and the blocking film include at least one among a silicon nitride (SiNx), a silicon oxide (SiOx), and a silicon oxynitride (SiOxNy).

4. The display device of claim 2, wherein
the blocking film is formed to intrude into at least a portion of the microcavity.

5. The display device of claim 4, wherein
the pixel electrode includes a first sub-pixel electrode and a second sub-pixel electrode that are positioned on opposite sides of where the injection hole is located, and
the third insulating layer is formed to a boundary of the first sub-pixel electrode and the second sub-pixel electrode.

6. The display device of claim 1, further comprising:
a color filter formed under the first insulating layer at a position corresponding to the plurality of pixel areas; and
a light blocking member formed under the first insulating layer at a position corresponding to the injection hole, wherein
the blocking film is formed at the position corresponding to the light blocking member.

7. The display device of claim 6, wherein
the blocking film is formed of an inorganic layer.

8. The display device of claim 7, wherein
the blocking film includes at least one among a silicon nitride (SiNx), a silicon oxide (SiOx), and a silicon oxynitride (SiOxNy).

9. The display device of claim 7, wherein
the blocking film is formed to intrude into at least a portion of the microcavity.

10. The display device of claim 9, wherein
the pixel electrode includes a first sub-pixel electrode and a second sub-pixel electrode that are positioned on opposite sides of where the injection hole is located, and
the third insulating layer is formed to a boundary of the first sub-pixel electrode and the second sub-pixel electrode.

11. The display device of claim 6, wherein
the blocking film is formed to intrude into at least a portion of the microcavity.

12. A method for manufacturing a display device, comprising:
forming a thin film transistor on a substrate;
forming a first insulating layer on the thin film transistor;
forming a pixel electrode connected to the thin film transistor on the first insulating layer;
forming a sacrificial layer on the pixel electrode;
forming a common electrode on the sacrificial layer;
forming a second insulating layer on the common electrode;
coating and patterning an organic material on the second insulating layer to form a roof layer;
patterning the second insulating layer and the common electrode by using the roof layer as a mask to expose the sacrificial layer;
removing the exposed sacrificial layer to form a microcavity between the pixel electrode and the common electrode and an injection hole;
injecting an alignment material into the microcavity through the injection hole to form an alignment layer inside the microcavity and on a surface of the injection hole;
forming a third insulating layer and a blocking film on a surface of the roof layer and the injection hole;
injecting a liquid crystal material into the microcavity to form a liquid crystal layer; and
forming an overcoat on the third insulating layer to seal the microcavity.

13. The method of claim 12, wherein
the third insulating layer and the blocking film are simultaneously formed with the same material, and
the third insulating layer and the blocking film are formed of at least one among a silicon nitride (SiNx), a silicon oxide (SiOx), and a silicon oxynitride (SiOxNy).

14. The method of claim 13, wherein
the third insulating layer and the blocking film are formed by sputtering.

15. The method of claim 13, wherein
the pixel electrode includes a first sub-pixel electrode and a second sub-pixel electrode that are positioned on opposite sides of where the injection hole is located, and
the third insulating layer is formed to a boundary of the first sub-pixel electrode and the second sub-pixel electrode.

16. The method of claim 12, further comprising,
forming a color filter at each pixel area before forming the first insulating layer, and
forming a light blocking member on a boundary of each pixel area and on the thin film transistor before forming the first insulating layer, wherein
the blocking film is formed at a position corresponding to the light blocking member.

17. The method of claim 12, further comprising,
forming a color filter in the pixel area before forming the first insulating layer, and
after forming the first insulating layer, forming a light blocking member on the first insulating layer corresponding to the boundary of each pixel area and the thin film transistor, wherein
the blocking film is formed at a position corresponding to the light blocking member.
